(19) United States
(12) Patent Application Publication
(10) Pub. No.: US 2025/0138105 A1
(43) Pub. Date: May 1, 2025

(54) METHOD AND APPARATUS FOR DIAGNOSING DEVIATION ABNORMALITY IN ECO-FRIENDLY VEHICLE BATTERY CELLS

(71) Applicants: HYUNDAI MOTOR COMPANY, SEOUL (KR); KIA CORPORATION, SEOUL (KR)

(72) Inventor: Kyoung Hun Park, Hwaseong-si (KR)

(21) Appl. No.: 18/610,813

(22) Filed: Mar. 20, 2024

(30) Foreign Application Priority Data
Nov. 1, 2023 (KR) 10-2023-0149432

(51) Int. Cl. G01R 31/396; G01R 31/385; G01R 31/392

(52) U.S. Cl. CPC G01R 31/396; G01R 31/385; G01R 31/392

(57) ABSTRACT

A method for diagnosing voltage deviation abnormality in an eco-friendly vehicle battery cell includes determining whether a voltage deviation between a cell with a highest voltage and a cell with a lowest voltage among a plurality of cells constituting a battery of a vehicle is greater than or equal to a target voltage deviation, determining whether the battery satisfies a first condition, wherein the first condition is that a voltage of the cell with the lowest voltage is within a first threshold range or a voltage of the cell with the highest voltage continues for a period of time greater than or equal to a first threshold time while being greater than or equal to a target upper limit voltage, and determining voltage deviation abnormality of the battery if the battery satisfies the first condition.

### CROSS REFERENCE TO RELATED APPLICATIONS

The present application claims priority to Korean Patent Application No. 10-2023-0149432, filed Nov. 1, 2023, the entire contents of which is incorporated herein for all purposes by this reference.

### BACKGROUND

### Field

The disclosure relates to a method and apparatus for diagnosing deviation abnormality in a battery cell for an eco-friendly vehicle.

### Description of the Related Art

Eco-friendly vehicles such as hybrid electronic vehicles (HEVs), plug-in HEV (PHEVs), and electronic vehicles (EVs) have a built-in battery, which is a storage device to store electrical energy, to drive the motor of the vehicles. In particular, eco-friendly vehicles have a built-in high-voltage battery that is different from a low-voltage battery mounted on conventional internal combustion engine vehicles.

As these high-voltage batteries become increasingly dense and high-energy, even minor quality issues can lead to dangerous situations such as fire. Therefore, battery safety is becoming increasingly important.

Conventionally, in order to protect such high-voltage batteries, battery protection logic was developed for battery overvoltage, overtemperature, low voltage, cell voltage deviation, etc. However, since most high-voltage batteries catch fire while the vehicle is parked and charging, conventional high-voltage battery protection logics diagnose the fire risk of the battery by checking the battery voltage while the vehicle is parked and charging.

However, as substantial field claims have recently occurred due to vehicle battery problems while driving, technology is being developed to ensure driver safety by diagnosing the battery status even while driving.

Meanwhile, conventionally, when the battery voltage suddenly drops due to abnormal deterioration of the battery while the vehicle is driving, the speed of the voltage drop is so fast that a problem arises in which it is excluded from voltage deviation diagnosis.

In addition, a problem occurred in which a battery defect was not detected in the voltage sensing abnormality diagnosis logic and the vehicle continued to be driven without a fault diagnosis.

Therefore, in this technical field, there is a demand for technology that can ensure driver safety by diagnosing deterioration and abnormalities in high-voltage battery cells while the vehicle is driving.

### SUMMARY

The technical object of the disclosure is to provide a method and apparatus for diagnosing the deterioration of battery cells in an eco-friendly vehicle, which can ensure the safety of drivers by diagnosing the degree of deterioration and abnormalities in high-voltage battery cells while the vehicle is driving.

The technical objects to be achieved by the disclosure are not limited to the technical objects mentioned above, and other technical objects not mentioned may be clearly understood by those skilled in the art from the following descriptions.

In order to achieve the above object, a method for diagnosing voltage deviation abnormality in an eco-friendly vehicle battery cell according to an embodiment of the disclosure comprises the steps of determining whether a voltage deviation between a cell with a highest voltage and a cell with a lowest voltage among a plurality of cells constituting a battery of a vehicle is greater than or equal to a target voltage deviation, determine whether the battery satisfies a first condition, wherein the first condition is that a voltage of the cell with the lowest voltage is within a first threshold range or a voltage of the cell with the highest voltage continues for a period of time greater than or equal to a first threshold time while being greater than or equal to a target upper limit voltage, and determining voltage deviation abnormality of the battery if the battery satisfies the first condition.

Herein, the method for diagnosing voltage deviation abnormality in an eco-friendly vehicle battery cell may further comprise the steps of determining whether the battery satisfies a second condition if the battery does not satisfy the first condition, wherein the second condition is that the voltage of the cell with the lowest voltage is equal to or less than a first threshold voltage or the voltage of the cell with the highest voltage continues for a second threshold time while being greater than or equal to the target upper limit voltage, and an identifier (ID) of the cell with the lowest voltage when discharging the battery is the same as the ID of the cell with the highest voltage when charging the battery, and determining the voltage deviation abnormality of the battery if the battery satisfies the second condition.

Herein, the method for diagnosing voltage deviation abnormality in an eco-friendly vehicle battery cell may further comprise the steps of determining whether the battery satisfies a third condition if the battery does not satisfy the second condition, wherein the third condition is that the voltage of the cell with the lowest voltage is equal to or less than the first threshold voltage, or the voltage of the cell with the highest voltage continues for a third threshold time while being greater than or equal to the target upper limit voltage, and the identifier (ID) of the cell with the lowest voltage when discharging the battery is different from the ID of the cell with the highest voltage when charging the battery, and determining voltage sensing abnormality of the battery if the battery satisfies the third condition.

Herein, the method for diagnosing voltage deviation abnormality in an eco-friendly vehicle battery cell may further comprise the steps of notifying a driver of the voltage deviation abnormality of the battery if the battery satisfies the first condition, and limiting a charge power and discharge power of the battery within a threshold power.

Herein, the method for diagnosing voltage deviation abnormality in an eco-friendly vehicle battery cell may further comprise the steps of notifying a driver of the voltage deviation abnormality of the battery if the battery satisfies the second condition, and limiting a charge power and discharge power of the battery within a threshold power.

Herein, the method for diagnosing voltage deviation abnormality in an eco-friendly vehicle battery cell may further comprise the steps of notifying a driver of the voltage sensing abnormality of the battery if the battery satisfies the third condition, and limiting a charge power and discharge power of the battery within a threshold power.

Herein, the step of determining whether the battery satisfies the first condition may be performed when the voltage deviation between the cell with the highest voltage and the cell with the lowest voltage is greater than or equal to the target voltage deviation.

Herein, in the step of notifying the driver of the voltage deviation abnormality of the battery, the voltage deviation abnormality of the battery may be notified to the driver by turning on a warning light.

Herein, the first threshold range may be greater than a voltage sensing abnormality diagnosis voltage and equal to or less than a cell lower limit voltage.

Herein, the first threshold time and the second threshold time may be the same time.

Further, an apparatus for diagnosing voltage deviation abnormality in an eco-friendly vehicle battery cell according to an embodiment of the disclosure comprises a battery that stores power energy for driving a vehicle and includes a plurality of cells, a sensor that includes a voltage sensor that detects voltages of the plurality of cells, and a battery management unit that determine whether a voltage deviation between a cell with a highest voltage and a cell with a lowest voltage among the plurality of cells constituting the battery of a vehicle is greater than or equal to a target voltage deviation, determine whether the battery satisfies a first condition, wherein the first condition is that a voltage of the cell with the lowest voltage is within a first threshold range or a voltage of the cell with the highest voltage continues for a period of time greater than or equal to a first threshold time while being greater than or equal to a target upper limit voltage; and determines voltage deviation abnormality of the battery if the battery satisfies the first condition.

Herein, the battery management unit may determine whether the battery satisfies a second condition if the battery does not satisfy the first condition, wherein the second condition is that the voltage of the cell with the lowest voltage is equal to or less than a first threshold voltage or the voltage of the cell with the highest voltage continues for a second threshold time while being greater than or equal to the target upper limit voltage, and an identifier (ID) of the cell with the lowest voltage when discharging the battery is the same as the ID of the cell with the highest voltage when charging the battery, and the battery management unit may determine the voltage deviation abnormality of the battery if the battery satisfies the second condition.

Herein, the battery management unit may determine whether the battery satisfies a third condition if the battery does not satisfy the second condition, wherein the third condition is that the voltage of the cell with the lowest voltage is equal to or less than the first threshold voltage, or the voltage of the cell with the highest voltage continues for a third threshold time while being greater than or equal to the target upper limit voltage, and the identifier (ID) of the cell with the lowest voltage when discharging the battery is different from the ID of the cell with the highest voltage when charging the battery, and the battery management unit may determine voltage sensing abnormality of the battery if the battery satisfies the third condition.

Herein, the battery management unit may notify a driver of the voltage deviation abnormality of the battery if the battery satisfies the first condition, and limit a charge power and discharge power of the battery within a threshold power.

Herein, the battery management unit may notify a driver of the voltage deviation abnormality of the battery if the battery satisfies the second condition, and limit a charge power and discharge power of the battery within a threshold power.

Herein, the battery management unit may notify a driver of the voltage sensing abnormality of the battery if the battery satisfies the third condition, and limit a charge power and discharge power of the battery within a threshold power.

Herein, the battery management unit may determine whether the battery satisfies the first condition when the voltage deviation between the cell with the highest voltage and the cell with the lowest voltage is greater than or equal to the target voltage deviation.

Herein, the battery management unit may notify the driver of the voltage deviation abnormality of the battery by turning on a warning light.

Herein, the first threshold range may be greater than a voltage sensing abnormality diagnosis voltage and equal to or less than a cell lower limit voltage.

Herein, the first threshold time and the second threshold time may be the same time.

Through various embodiments of the disclosure as described above, signs of battery abnormality can be detected in advance.

Additionally, it is possible to ensure driver safety by diagnosing deterioration and abnormalities in high-voltage battery cells while the vehicle is driving.

The effects that can be achieved through the embodiments of the present disclosure are not limited to what has been particularly described hereinabove and other effects which are not described herein can be derived by those skilled in the art from the following detailed description.

### BRIEF DESCRIPTION OF THE FIGURES

FIG. 1 is a block diagram schematically illustrating an apparatus for diagnosing deterioration of a battery cell according to an embodiment of the disclosure.

FIG. 2 is a graph illustrating an example of the voltage change of an abnormally deteriorated battery cell according to an embodiment of the disclosure.

FIG. 3 is an enlarged graph illustrating the discharge and regeneration period 210 in the graph of FIG. 2.

FIG. 4 is a flowchart illustrating a method for diagnosing deterioration of a battery cell according to an embodiment of the disclosure.

### DETAILED DESCRIPTION

Hereinafter, embodiments of the disclosure will be described in detail with reference to the attached drawings. The same or similar components are given the same reference numbers and redundant description thereof is omitted. The suffixes “module” and “unit” of elements herein are used for convenience of description and thus can be used interchangeably and do not have any distinguishable meanings or functions. Further, in the description of the embodiment of the disclosure, if a detailed description of known techniques associated with the present disclosure would unnecessarily obscure the gist of the present disclosure, detailed description thereof will be omitted. In addition, the attached drawings are provided for easy understanding of embodiments of the disclosure and do not limit technical spirits of the disclosure, and the embodiments should be construed as including all modifications, equivalents, and alternatives falling within the spirit and scope of the embodiments.

While terms, such as “first”, “second”, etc., may be used to describe various components, such components must not be limited by the above terms. The above terms are used only to distinguish one component from another.

When an element is “coupled” or “connected” to another element, it should be understood that it can be directly connected or coupled to the other element or intervening elements may be present. In contrast, when an element is referred to as being “directly connected” or “directed coupled” to another element, it should be understood that no element is present between the two elements.

The singular forms are intended to include the plural forms as well, unless the context clearly indicates otherwise.

In the specification, it will be understood that the terms “comprise” or “have” specify the presence of stated features, integers, steps, operations, elements, components, or combinations thereof, but do not preclude the presence or addition of one or more other features, integers, steps, operations, elements, components, or combinations.

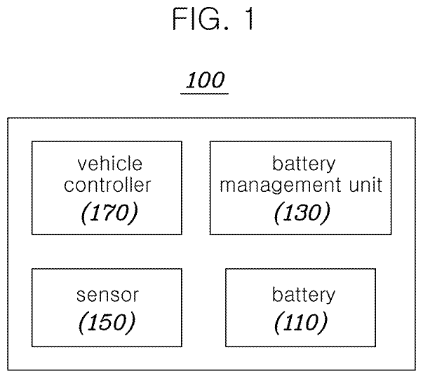

FIG. 1 is a block diagram schematically illustrating an apparatus for diagnosing deterioration of a battery cell according to an embodiment of the disclosure.

Referring to FIG. 1, an apparatus for diagnosing voltage abnormality of a battery cell according to the embodiment includes a battery 110, a battery management unit 130, a sensor 150, and a vehicle controller 170.

The battery 110 stores power energy for driving a vehicle and includes a plurality of cells.

The battery management unit 130 determines whether a cell voltage deviation is greater than or equal to a target voltage deviation when the vehicle ignition is on (IG ON).

In the specification, cell voltage deviation refers to a voltage difference between a cell with the highest voltage and a cell with the lowest voltage among the plurality of cells constituting the battery 110.

Additionally, in the specification, the cell with the highest voltage is defined as a maximum (Max) cell, and the cell with the lowest voltage is defined as a minimum (Min) cell.

Therefore, in the specification, the cell voltage deviation may be defined as the voltage difference between the maximum cell and the minimum cell.

In this case, the target voltage deviation may be set to various values, for example, 1V.

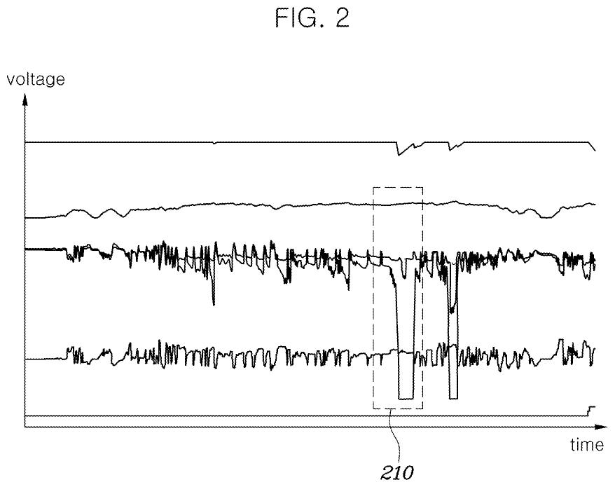

FIG. 2 is a graph illustrating an example of the voltage change of an abnormally deteriorated battery cell according to an embodiment of the disclosure.

Meanwhile, when deterioration occurs in some of the cells of the battery 110, the internal resistance of the deteriorated cells increases as illustrated FIG. 2, and the voltage of the cells rapidly decreases for a certain period of time (210) and then rapidly recovers again.

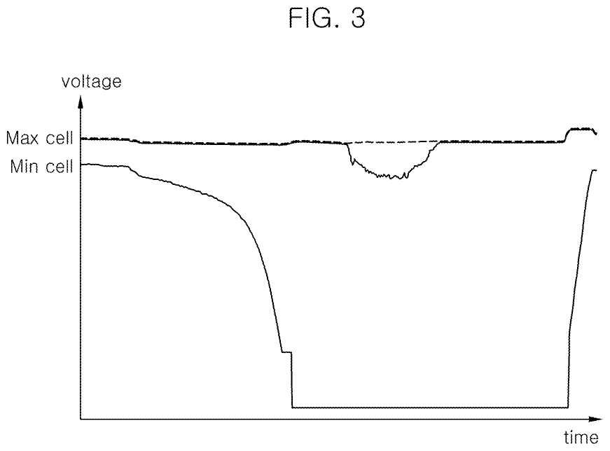

FIG. 3 is an enlarged graph illustrating the discharge and regeneration period 210 in the graph of FIG. 2.

Referring to FIG. 3, it can be seen that the cell voltage deviation, which is the voltage difference between the maximum cell and the minimum cell, gradually increases for a certain time, is maintained for a certain time, and then decreases again for a certain time.

In this case, the reason for determining the cell voltage deviation is that in the case of a cell whose internal resistance has increased due to battery deterioration, the voltage drops sharply as illustrated FIG. 3 during driving.

Additionally, the battery management unit 130 determines whether the battery 110 satisfies a first condition.

In this case, the first condition represents a condition in which the voltage of the minimum cell is within a first threshold range or the voltage of the maximum cell continues for a period of time greater than or equal to a first threshold time while being greater than or equal to a target upper limit voltage.

Herein, the first threshold range represents a range that is greater than a voltage sensing abnormality diagnosis voltage and equal to or less than a cell lower limit voltage.

Herein, the voltage sensing abnormality diagnosis voltage may be defined as a first threshold voltage, the cell lower limit voltage may be defined as a second threshold voltage, and the target upper limit voltage may be defined as a third threshold voltage.

Herein, the voltage sensing abnormality diagnosis voltage may be set to various values, for example, 0.5V.

Herein, the cell lower limit voltage may be set to various values, for example, 2.5V.

Herein, the first threshold time may be set to various values, for example, 1 second.

Meanwhile, when the battery 110 satisfies the first condition, the battery management unit 130 determines the voltage deviation abnormality of the high-voltage battery, notifies the driver that the voltage deviation of the high-voltage battery is abnormal, and limits the charge power and discharge power of the battery within a certain range.

Herein, the battery management unit 130 may notify the voltage deviation abnormality of the high-voltage battery by turning on a warning light.

For example, the battery management unit 130 may limit the battery charge power and battery discharge power within 10 kW.

Additionally, if the battery 110 does not satisfy the first condition, the battery management unit 130 determines whether the second condition is satisfied.

Herein, the second condition represents that the voltage of the minimum cell is equal to or less than the voltage sensing abnormality diagnosis voltage, or the voltage of the maximum cell continues for a second threshold time while being greater than or equal to the target upper limit voltage, and the identifier (ID) of the minimum cell when the battery 110 is discharged indicates the same condition as the ID of the maximum cell when the battery is charged.

Herein, the voltage sensing abnormality diagnosis voltage may be defined as the first threshold voltage, and the target upper limit voltage may be defined as the second threshold voltage.

Herein, the voltage sensing abnormality diagnosis voltage may be set to various values, for example, 0.5V.

Herein, the second threshold time may be set to various values, for example, 1 second.

Herein, the first threshold time and the second threshold time may be set to the same time.

Meanwhile, when the battery 110 satisfies the second condition, the battery management unit 130 determines the voltage deviation abnormality of the high-voltage battery, notifies the driver that the voltage deviation of the high-voltage battery is abnormal, and limits the charge power and discharge power of the battery within a certain range.

Herein, the battery management unit 130 may notify the voltage deviation abnormality of the high-voltage battery by turning on a warning light.

For example, the battery management unit 130 may limit the battery charge power and battery discharge power within 10 kW.

Additionally, if the battery 110 does not satisfy the second condition, the battery management unit 130 determines whether the third condition is satisfied.

Herein, the third condition represents that the voltage of the minimum cell is equal to or less than the voltage sensing abnormality diagnosis voltage, or the voltage of the maximum cell is greater than or equal to the target upper limit voltage, and the identifier (ID) of the minimum cell when discharging the battery 110 is different from the ID of the maximum cell when charging the battery, and the condition continues for a period of time greater than or equal to a third threshold time while satisfying the above conditions.

Herein, the voltage sensing abnormality diagnosis voltage may be set to various values, for example, 0.5V.

Herein, the third threshold time may be set to various values, for example, 35 seconds.

Meanwhile, when the battery 110 satisfies the third condition, the battery management unit 130 diagnoses that there is an abnormality in the high-voltage battery voltage sensing, notifies the driver that there is an abnormality in the high-voltage battery voltage sensing, and limits the charge power and discharge power of the battery within a certain range.

Herein, the battery management unit 130 may notify that the voltage deviation abnormality of the high-voltage battery by turning on a warning light.

For example, the battery management unit 130 may limit the battery charge power and battery discharge power within 10 kW.

The sensor 150 measures the voltage of the battery 110.

Herein, the sensor 150 may measure all changes in voltage of cells constituting the battery 110.

The vehicle controller 170 controls the vehicle based on the output of the battery 110.

Herein, the vehicle controller 170 receives information about the occurrence of a voltage deviation abnormality or voltage sensing abnormality in the cell of the battery 110 from the battery management unit 130 and controls the vehicle based on this information.

For example, when the vehicle controller 170 receives information about the occurrence of a voltage deviation abnormality in a cell of the battery 110 from the battery management unit 130, the vehicle controller 170 may turn on the vehicle's warning light to notify the driver of the occurrence.

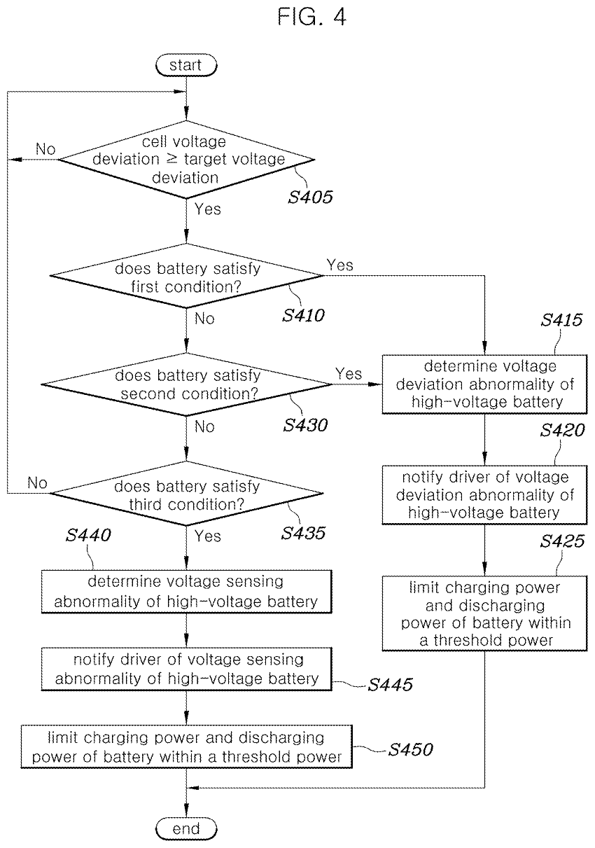

FIG. 4 is a flowchart illustrating a method for diagnosing deterioration of a battery cell according to an embodiment of the disclosure.

The deterioration diagnosis method according to an embodiment may be performed by the battery management unit 130 of the deterioration diagnosis apparatus 100 according to the embodiment of FIG. 1.

Referring to FIG. 4, the battery management unit 130 determines whether the cell voltage deviation is greater than or equal to the target voltage deviation when the vehicle ignition is on (IG ON) (S405).

In this specification, cell voltage deviation refers to a voltage difference between a cell with the highest voltage and a cell with the lowest voltage among the plurality of cells constituting the battery 110.

Additionally, in the specification, the cell with the highest voltage is defined as a maximum (Max) cell, and the cell with the lowest voltage is defined as a minimum (Min) cell.

Therefore, in the specification, the cell voltage deviation may be defined as a voltage difference between the maximum cell and the minimum cell.

Herein, the target voltage deviation may be set to various values, for example, 1V.

Additionally, the battery management unit 130 determines whether the battery 110 satisfies a first condition (S410).

Herein, the first condition represents a condition in which the voltage of the minimum cell is within a first threshold range or the voltage of the maximum cell continues for a period of time greater than or equal to a first threshold time while being greater than or equal to a target upper limit voltage.

Herein, the first threshold range represents a range that is greater than a voltage sensing abnormality diagnosis voltage and equal to or less than a cell lower limit voltage.

Herein, the voltage sensing abnormality diagnosis voltage may be defined as a first threshold voltage, the cell lower limit voltage may be defined as a second threshold voltage, and the target upper limit voltage may be defined as a third threshold voltage.

Herein, the voltage sensing abnormality diagnosis voltage may be set to various values, for example, 0.5V.

Herein, the cell lower limit voltage may be set to various values, for example, 2.5V.

Herein, the first threshold time may be set to various values, for example, 1 second.

Meanwhile, when the battery 110 satisfies the first condition, the battery management unit 130 determines the voltage deviation abnormality of the high-voltage battery (S415), notifies the driver of the voltage deviation abnormality of the high-voltage battery (S420), and limits the charge power and discharge power of the battery 110 within a threshold power (S425).

Herein, the battery management unit 130 may notify the voltage deviation abnormality of the high-voltage battery by turning on a warning light.

For example, the threshold power may be 10 kW.

Additionally, if the battery 110 does not satisfy the first condition, the battery management unit 130 determines whether the second condition is satisfied (S430).

Herein, the second condition represents that the voltage of the minimum cell is equal to or less than the voltage sensing abnormality diagnosis voltage, or the voltage of the maximum cell continues for a second threshold time while being greater than or equal to the target upper limit voltage, and the identifier (ID) of the minimum cell when the battery 110 is discharged indicates the same condition as the ID of the maximum cell when the battery is charged.

Herein, the voltage sensing abnormality diagnosis voltage may be defined as the first threshold voltage, and the target upper limit voltage may be defined as the second threshold voltage.

Herein, the voltage sensing abnormality diagnosis voltage may be set to various values, for example, 0.5V.

Herein, the second threshold time may be set to various values, for example, 1 second.

Herein, the first threshold time and the second threshold time may be set to the same time.

Meanwhile, when the battery 110 satisfies the second condition, the battery management unit 130 determines the voltage deviation abnormality of the high-voltage battery (S415), notifies the driver of the voltage deviation abnormality of the high-voltage battery (S420), and limits the charging power and discharge power of the battery within a threshold power (S425).

Herein, the battery management unit 130 may notify that the voltage deviation abnormality of the high-voltage battery by turning on a warning light.

For example, the threshold power may be 10 kW.

Additionally, if the battery 110 does not satisfy the second condition, the battery management unit 130 determines whether the third condition is satisfied (S435).

Herein, the third condition represents that the voltage of the minimum cell is equal to or less than the voltage sensing abnormality diagnosis voltage, or the voltage of the maximum cell is greater than or equal to the target upper limit voltage, and the identifier (ID) of the minimum cell when discharging the battery 110 is different from the ID of the maximum cell when charging the battery, and the condition continues for a period of time greater than or equal to a third threshold time while satisfying the above conditions.

Herein, the voltage sensing abnormality diagnosis voltage may be set to various values, for example, 0.5V.

Herein, the third threshold time may be set to various values, for example, 35 seconds.

Meanwhile, when the battery 110 satisfies the third condition, the battery management unit 130 diagnoses that there is an abnormality in the high-voltage battery voltage sensing (S440), notifies the driver that there is an abnormality in the high-voltage battery voltage sensing (S445), and limits the charge power and discharge power of the battery within a threshold power (S450).

Herein, the battery management unit 130 may notify that the voltage deviation abnormality of the high-voltage battery by turning on a warning light.

For example, the threshold power may be 10 kW.

The sensor 150 measures the voltage of the battery 110.

Herein, the sensor 150 may measure all changes in voltage of cells constituting the battery 110.

The vehicle controller 170 controls the vehicle based on the output of the battery 110.

Herein, the vehicle controller 170 receives information about the occurrence of a voltage deviation abnormality or voltage sensing abnormality in the cell of the battery 110 from the battery management unit 130 and controls the vehicle based on this information.

For example, when the vehicle controller 170 receives information about the occurrence of a voltage deviation abnormality in a cell of the battery 110 from the battery management unit 130, the vehicle controller 170 may turn on the vehicle's warning light to notify the driver of the occurrence.

According to the embodiments of the disclosure described so far, signs of battery abnormality can be detected in advance.

In addition, a logic is provided to diagnose a high-voltage battery by diagnosing cells with abnormalities using cell balancing technology to balance the voltage deviation of the high-voltage battery.

In addition, it is possible to ensure driver safety by diagnosing deterioration and abnormalities in high-voltage battery cells while the vehicle is driving.

Meanwhile, the disclosure described above may be implemented in computer-readable codes in a computer readable recording medium, and the computer readable recording medium may include all kinds of recording devices for storing data that is readable by a computer system. Examples of the computer readable recording medium include HDD (Hard Disk Drive), SSD (Solid State Disk), SDD (Silicon Disk Drive), ROM, RAM, CD-ROM, magnetic tape, floppy disk, optical data storage device, and the like. Accordingly, the foregoing detailed description should not be interpreted as restrictive in all aspects, and should be considered as illustrative. The scope of the disclosure should be determined by rational interpretation of the appended claims, and all changes within the equivalent scope of the present disclosure are included in the scope of the disclosure.

Although the present disclosure was provided above in relation to specific embodiments shown in the drawings, it is apparent to those skilled in the art that the present disclosure may be changed and modified in various ways without departing from the scope of the present disclosure, which is provided in the following claims.

1. A method for diagnosing voltage deviation abnormality in an eco-friendly vehicle battery cell, comprising the steps of:
determining, by a battery management unit, whether a voltage deviation between a cell with a highest voltage and a cell with a lowest voltage among a plurality of cells constituting a battery of a vehicle is greater than or equal to a target voltage deviation;
determining whether the battery satisfies a first condition, wherein the first condition is that a voltage of the cell with the lowest voltage is within a first threshold range or a voltage of the cell with the highest voltage continues for a period of time greater than or equal to a first threshold time while being greater than or equal to a target upper limit voltage; and
determining voltage deviation abnormality of the battery when the battery satisfies the first condition.

2. The method of claim 1, further comprising the steps of:
determining whether the battery satisfies a second condition if the battery does not satisfy the first condition, wherein the second condition is that the voltage of the cell with the lowest voltage is equal to or less than a first threshold voltage or the voltage of the cell with the highest voltage continues for a second threshold time while being greater than or equal to the target upper limit voltage, and an identifier (ID) of the cell with the lowest voltage when discharging the battery is the same as the ID of the cell with the highest voltage when charging the battery; and
determining the voltage deviation abnormality of the battery when the battery satisfies the second condition.

3. The method of claim 2, further comprising the steps of:
determining whether the battery satisfies a third condition if the battery does not satisfy the second condition, wherein the third condition is that the voltage of the cell with the lowest voltage is equal to or less than the first threshold voltage, or the voltage of the cell with the highest voltage continues for a third threshold time while being greater than or equal to the target upper limit voltage, and the identifier (ID) of the cell with the lowest voltage when discharging the battery is different from the ID of the cell with the highest voltage when charging the battery; and
determining voltage sensing abnormality of the battery when the battery satisfies the third condition.

4. The method of claim 1, further comprising the steps of:
notifying a driver of the voltage deviation abnormality of the battery when the battery satisfies the first condition; and
limiting a charge power and discharge power of the battery within a threshold power.

5. The method of claim 2, further comprising the steps of:
notifying a driver of the voltage deviation abnormality of the battery when the battery satisfies the second condition; and
limiting a charge power and discharge power of the battery within a threshold power.

6. The method of claim 3, further comprising the steps of:
notifying a driver of the voltage sensing abnormality of the battery when the battery satisfies the third condition; and
limiting a charge power and discharge power of the battery within a threshold power.

7. The method of claim 1, wherein determining whether the battery satisfies the first condition is performed when the voltage deviation between the cell with the highest voltage, and the cell with the lowest voltage is greater than or equal to the target voltage deviation.

8. The method of claim 4, wherein in the step of notifying the driver of the voltage deviation abnormality of the battery, the voltage deviation abnormality of the battery is notified to the driver by a warning light.

9. The method of claim 1, wherein the first threshold range is greater than a voltage sensing abnormality diagnosis voltage and equal to or less than a cell lower limit voltage.

10. The method of claim 2, wherein the first threshold time and the second threshold time are the same.

11. An apparatus for diagnosing voltage deviation abnormality in an eco-friendly vehicle battery cell, comprising:
a battery configured to store power energy for driving a vehicle and including a plurality of cells;
a sensor including a voltage sensor configured to detect voltages of the plurality of cells; and
a battery management unit configured to:
determine whether a voltage deviation between a cell with a highest voltage and a cell with a lowest voltage among the plurality of cells is greater than or equal to a target voltage deviation;
determine whether the battery satisfies a first condition, wherein the first condition is that a voltage of the cell with the lowest voltage is within a first threshold range or a voltage of the cell with the highest voltage continues for a period of time greater than or equal to a first threshold time while being greater than or equal to a target upper limit voltage; and
determine a voltage deviation abnormality of the battery if the battery satisfies the first condition.

12. The apparatus of claim 11, wherein the battery management unit is configured to determine whether the battery satisfies a second condition if the battery does not satisfy the first condition, wherein the second condition is that the voltage of the cell with the lowest voltage is equal to or less than a first threshold voltage or the voltage of the cell with the highest voltage continues for a second threshold time while being greater than or equal to the target upper limit voltage, and an identifier (ID) of the cell with the lowest voltage when discharging the battery is the same as the ID of the cell with the highest voltage when charging the battery, and
the battery management unit is configured to determine the voltage deviation abnormality of the battery when the battery satisfies the second condition.

13. The apparatus of claim 12, wherein the battery management unit is configured to determine whether the battery satisfies a third condition if the battery does not satisfy the second condition, wherein the third condition is that the voltage of the cell with the lowest voltage is equal to or less than the first threshold voltage, or the voltage of the cell with the highest voltage continues for a third threshold time while being greater than or equal to the target upper limit voltage, and the identifier (ID) of the cell with the lowest voltage when discharging the battery is different from the ID of the cell with the highest voltage when charging the battery, and
the battery management unit is configured to determine voltage sensing abnormality of the battery when the battery satisfies the third condition.

14. The apparatus of claim 11, wherein the battery management unit is configured to notify a driver of the voltage deviation abnormality of the battery when the battery satisfies the first condition, and to limit a charge power and discharge power of the battery within a threshold power.

15. The apparatus of claim 12, wherein the battery management unit is configured to notify a driver of the voltage deviation abnormality of the battery when the battery satisfies the second condition, and to limit a charge power and discharge power of the battery within a threshold power.

16. The apparatus of claim 13, wherein the battery management unit is configured to notify a driver of the voltage sensing abnormality of the battery when the battery satisfies the third condition, and to limit a charge power and discharge power of the battery within a threshold power.

17. The apparatus of claim 11, wherein the battery management unit is configured to determine whether the battery satisfies the first condition when the voltage deviation between the cell with the highest voltage and the cell with the lowest voltage is greater than or equal to the target voltage deviation.

18. The apparatus of claim 14, wherein the battery management unit is configured to notify the driver of the voltage deviation abnormality of the battery by a warning light.

19. The apparatus of claim 11, wherein the first threshold range is greater than a voltage sensing abnormality diagnosis voltage and equal to or less than a cell lower limit voltage.

20. The apparatus of claim 12, wherein the first threshold time and the second threshold time are the same time.
